(19) United States
(12) Patent Application Publication
(10) Pub. No.: US 2020/0336141 A1
(43) Pub. Date: Oct. 22, 2020

(54) SUPPLY VOLTAGE SUPERVISOR

(71) Applicant: TEXAS INSTRUMENTS INCORPORATED, Dallas, TX (US)

(72) Inventors: Santhosh Kumar S, Chennai (IN); Divya KAUR, Delhi (IN); Rajat CHAUHAN, Bengaluru (IN); Jayateerth Pandurang MATHAD, Bengaluru (IN); Tallam VISHWANATH, Bengaluru (IN); Vinod MENEZES, Bengaluru (IN)

(21) Appl. No.: 16/853,096

(22) Filed: Apr. 20, 2020

Related U.S. Application Data
(60) Provisional application No. 62/903,392, filed on Sep. 20, 2019.

(30) Foreign Application Priority Data
Apr. 20, 2019 (IN) 201941015752

(51) Int. Cl. H03K 17/22; H03K 17/30; H03K 17/00; H03K 3/023; G05F 3/26

(52) U.S. Cl. CPC H03K 17/223; H03K 17/302; G05F 3/262; H03K 3/023; H03K 17/002

(57) ABSTRACT

A supply voltage supervisor circuit includes a comparator circuit. The comparator circuit includes a first input terminal, a second input terminal, a first transistor, and a second transistor. The first transistor has a first threshold voltage, and includes a first terminal coupled to the first input terminal. The second transistor has a second threshold voltage that is different from the first voltage threshold, and includes a first terminal coupled to the second input terminal, and a second terminal coupled to a second terminal of the first transistor. A trip point of the comparator circuit is based on a difference of the first threshold voltage and the second threshold voltage.

### CROSS-REFERENCE TO RELATED APPLICATIONS

The present application claims priority to Indian Provisional Patent Application No. 201941015752, filed Apr. 20, 2019, entitled “Supply Voltage Supervisor Using Intrinsically Referenced Comparator,” and to U.S. Provisional Patent Application No. 62/903,392, filed Sep. 20, 2019, entitled “Supply Voltage Supervisor with Intrinsic Referenced Comparator,” each of which is hereby incorporated herein by reference in its entirety.

### BACKGROUND

Voltage supervisors are employed in many applications (such as automotive infotainment systems, industrial systems, cell phone, personal electronic devices, wearable device, etc.) to detect over-voltage or under-voltage conditions of a power supply. In one example, the power supply for a mobile device is a battery that is monitored by the voltage supervisor to detect low battery conditions. If the battery voltage drops below a given threshold, the voltage supervisor can detect the condition by comparing the battery voltage to a threshold. The voltage supervisor can then signal the processing elements in the mobile device to alert the user and in very low voltage cases, can initiate an orderly shutdown of the device.

### SUMMARY

A supply voltage supervisor circuit that generates the reference voltage in the comparator based on the threshold voltages of the input transistors. In one example, a supply voltage supervisor circuit includes a comparator circuit. The comparator circuit includes a first input terminal, a second input terminal, a first transistor, and a second transistor. The first transistor has a first threshold voltage, and includes a first terminal coupled to the first input terminal. The second transistor has a second threshold voltage different from the first threshold voltage, and includes a first terminal coupled to the second input terminal, and a second terminal coupled to a second terminal of the first transistor. A trip point of the comparator circuit is based on a difference of the first threshold voltage and the second threshold voltage.

In another example, a supply voltage supervisor circuit includes a comparator circuit and a reference voltage circuit. The reference voltage circuit includes a reference output terminal, a plurality of resistors coupled in series, an N-channel natural threshold voltage metal oxide semiconductor field effect transistor (MOSFET), an N-channel standard threshold voltage MOSFET, and a selector circuit. The reference output terminal is coupled to an input terminal of the comparator circuit. The N-channel natural threshold voltage MOSFET includes a first terminal coupled to a power rail, and a second terminal coupled to a current input terminal of the resistors. The N-channel standard threshold voltage MOSFET includes a first terminal coupled to a current output terminal of the resistors, a second terminal coupled to a ground rail, and a third terminal coupled to a third terminal of the N-channel natural threshold voltage MOSFET. The selector circuit includes a plurality of input terminals coupled to the resistors, and a selector output terminal coupled to the reference output terminal.

In a further example, a comparator circuit includes a first input terminal, a second input terminal, a first transistor, a second transistor, and a current mirror circuit. The first transistor has a first threshold voltage, and includes a first terminal coupled to the first input terminal. The second transistor has a second threshold voltage that is different from the first threshold voltage, and includes a first terminal coupled to the second input terminal, and a second terminal coupled to a second terminal of the first transistor. The current mirror circuit includes a diode-connected transistor and a third transistor. The diode-connected transistor includes a first terminal coupled to a power supply rail, and a second terminal and a third terminal coupled to a third terminal of the first transistor. The third transistor includes a first terminal coupled to a power supply rail, a second terminal coupled to a third terminal of the second transistor, and a third terminal coupled to the third terminal of the diode-connected transistor. A trip point of the comparator circuit is based on a difference of the first threshold voltage and the second threshold voltage.

### BRIEF DESCRIPTION OF THE DRAWINGS

For a detailed description of various examples, reference will now be made to the accompanying drawings in which:

FIG. 1 shows block diagram for an example system that includes a supply voltage supervisor circuit;

FIG. 2 shows a schematic diagram for an example supply voltage supervisor circuit;

FIG. 3 shows a block diagram for an example supply voltage supervisor circuit that generates a reference voltage as a comparator input offset in accordance with this description;

FIGS. 4 and 5 show schematic diagrams for an example supply voltage supervisor circuits that generates a reference voltage based on different threshold voltages of the comparator input transistors in accordance with this description;

FIG. 6 shows normalized reference voltage versus temperature for examples of a supply voltage supervisor circuit that generates a reference voltage based on different threshold voltages of the comparator input transistors in accordance with this description;

FIG. 7 shows an example reference voltage generation circuit that generates a reference voltage based on different threshold voltages of transistors in accordance with this description;

FIG. 8 shows reference voltage versus temperature for examples of the reference voltage generation circuit of FIG. 7; and

FIGS. 9-12 shows example supply voltage supervisor circuits that generate a reference voltage based on different threshold voltages of the comparator input transistors and include trim transistors for temperature variation correction in accordance with this description.

### DETAILED DESCRIPTION

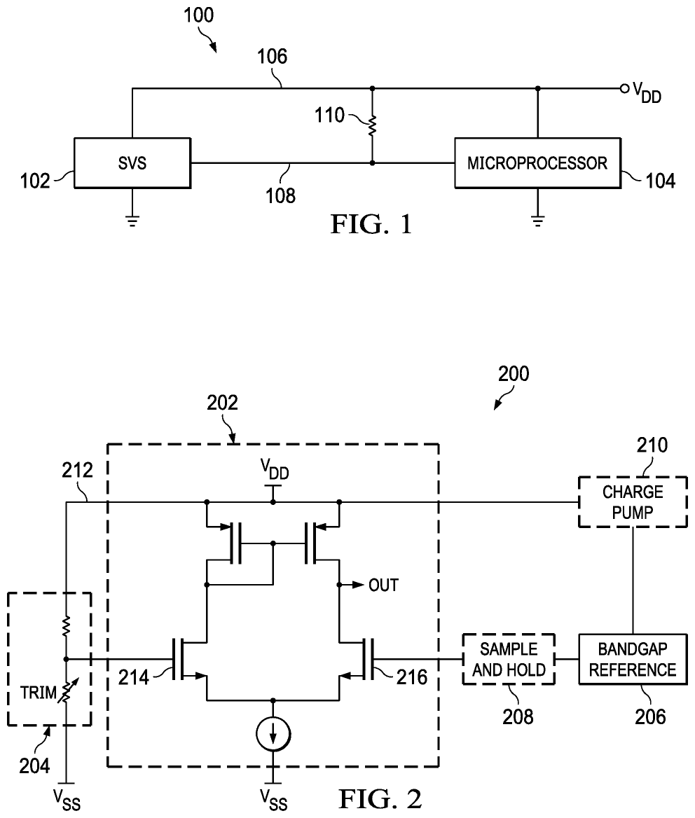

Supply voltage supervisors compare a power supply voltage (or other voltage) to a reference voltage to determine whether the power supply voltage is within the operational voltage range of circuitry being powered by the power supply voltage. FIG. 1 shows a block diagram for an example system 100 that includes a supply voltage supervisor circuit 102 and a microprocessor 104. The supply voltage supervisor circuit 102 and the microprocessor 104 are coupled to a power supply rail 106 and ground. Voltage on the power supply rail 106 powers the microprocessor 104. The supply voltage supervisor circuit 102 monitors the voltage on the power supply rail 106, and generates a signal 108 that is indicative of the state of the voltage on the power supply rail 106. For example, the supply voltage supervisor circuit 102 compares the voltage on the power supply rail 106 to a reference voltage and deactivates the signal 108 to enable operation of the microprocessor 104 if the voltage on the power supply rail 106 exceeds the reference voltage. Similarly, the supply voltage supervisor circuit 102 activates the signal 108 if the voltage on the power supply rail 106 is lower than the reference voltage to disable operation of the microprocessor 104. Thus, the supply voltage supervisor circuit 102 ensures that the microprocessor 104 is enabled only when the voltage on the power supply rail 106 exceeds the reference voltage.

Some supply voltage supervisors include a bandgap reference circuit that generates the reference voltage. FIG. 2 shows a schematic diagram for an example supply voltage supervisor circuit 200. The supply voltage supervisor circuit 200 includes a comparator 202, a voltage divider 204, and a bandgap reference circuit 206. The voltage divider 204 divides the voltage provided on the power supply rail 212 to a voltage to be compared with the reference voltage generated by the bandgap reference circuit 206. The comparator 202 includes matched input transistors 214 and 216 that compare the output of the voltage divider 204 to the reference voltage generated by the bandgap reference circuit 206.

The bandgap reference circuit 206, and bandgap reference circuits in general, are complex and relatively large in terms of circuit area, draw a relatively high quiescent current, and have a relatively high operating voltage. To reduce the quiescent current drawn by the bandgap reference circuit, some implementations of the supply voltage supervisor circuit 200 include the sample and hold circuitry 208 at the output of the bandgap reference circuit 206, which further increases circuit area and cost. To enable operation with lower power supply voltages, some implementations of the supply voltage supervisor circuit 200 include a charge pump 210 that powers the bandgap reference circuit 206, which again increases circuit area and cost.

At least some examples of the supply voltage supervisors disclosed herein implement reference voltage generation within the comparator input circuitry, and therefore do not require a reference circuit, such as a bandgap reference circuit, external to the comparator. These supply voltage generators provide the reference voltage as an input offset in the comparator. The input transistors of the comparator are selected such that a difference in threshold voltage of the transistors defines the reference voltage. Lack of reference voltage circuitry greatly reduces the circuit area and quiescent current of the supply voltage supervisors relative to other implementations and allows for operation with low power supply voltages (e.g., less than 1 volt). Unlike bandgap reference generation circuits, no start-up circuitry is needed, and implementations provide fast response.

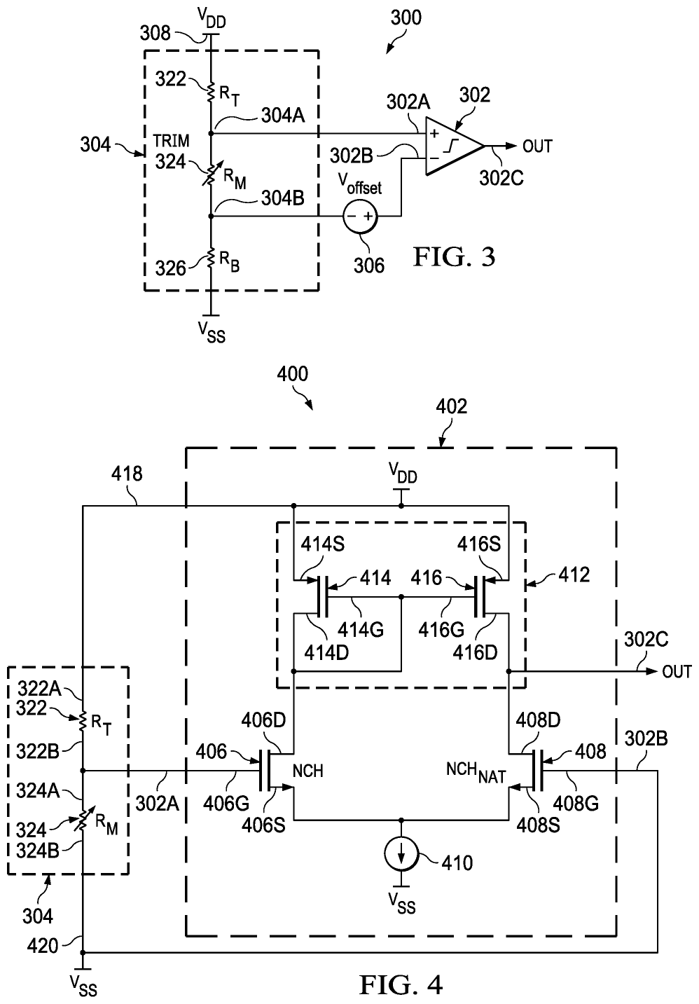

FIG. 3 shows a block diagram for an example supply voltage supervisor circuit 300 that generates a reference voltage as a comparator input offset in accordance with this description. The supply voltage supervisor circuit 300 includes a comparator 302, a voltage divider 304, and a voltage source 306. The non-inverting input of the comparator 302 is coupled to node 304A of the voltage divider 304, and the inverting input of the comparator 302 is coupled to the node 304B of the voltage divider 304 via the voltage source 306. The supply voltage supervisor circuit 300 effectively compares the voltage on the power rail 308 to a reference voltage without inclusion of a bandgap reference circuit or other external reference voltage generation circuitry. The voltage divider 304 and the voltage source 306 set the trip voltage of the comparator 302 as:

$${V}_{trip} = \frac{{V}_{offset} ( {R}_{T} + {R}_{M} + {R}_{B} )}{{R}_{M}} \qquad ( 1 )$$

While FIG. 3 illustrates setting the trip voltage of a comparator using an offset generated external to the comparator, some implementations apply the threshold voltages of the comparator input transistors to generate the offset. FIG. 4 shows a schematic diagram for an example supply voltage supervisor circuit 400 that generates a reference voltage based on different threshold voltages of the comparator input transistors in accordance with an example embodiment. The supply voltage supervisor circuit 400 includes a comparator 402, and a voltage divider 404. The voltage divider 404 divides the voltage provided on the power supply rail 418 to a voltage to be provided to the comparator 402. The voltage divider 404 includes a fixed resistor 322 and a variable resistor 324. A terminal 322A of the resistor 322 is coupled to the power supply rail 418. A terminal 324A of the resistor 324 is coupled to a terminal 322B of the resistor 324. A terminal 324B of the resistor 324 is coupled to a ground rail 420.

The comparator 402 includes an input terminal 302A, an input terminal 302B, a transistor 406, a transistor 408, a current source 410, and a current mirror circuit 412. The input terminal 302A is coupled to the terminal 322B of the resistor 322 for receipt of the divided power rail voltage. The input terminal 302B is coupled to the ground rail 420 in some implementations. The current mirror circuit 412 includes a diode-connected PMOS transistor 414 and another PMOS transistor 416. The diode-connected transistor 414 includes a source terminal 414S coupled to the power supply rail 418, and a gate terminal 414G coupled to a drain terminal 414D. The transistor 416 includes a source terminal 416S coupled to the power supply rail 418, a gate terminal 416G coupled to the gate terminal 414G of the diode-connected transistor 414, and a drain terminal 416D coupled to an output terminal 302C of the comparator 402. While transistors are shown as PMOS transistors, in alternative embodiments they can be implemented with NMOS transistors or bipolar junction transistors (such as NPN or PNP transistors).

The transistor 406 includes a gate terminal 406G coupled to the input terminal 302A, a drain terminal 406D coupled to the drain terminal 414D of the diode-connected transistor 414, and a source terminal 406S coupled to the current source 410. The transistor 408 includes a gate terminal 408G coupled to the input terminal 302B, a drain terminal 408D coupled to the drain terminal 416D of the transistor 416, and a source terminal 408S coupled to the current source 410. The current source 410 maintains a fixed bias current in the comparator 402 so that the current in the comparator 402 does not vary with comparator input voltage (e.g., voltage at the input terminal 302A).

The transistor 406 is a standard threshold voltage N-channel metal oxide semiconductor field effect transistor (MOSFET) in some implementations of the supply voltage supervisor circuit 400. A standard threshold voltage N-channel MOSFET has a threshold of about 0.7 volts. The transistor 408 is natural N-channel MOSFET. A natural MOSFET has a threshold of about −60 millivolts. Additional examples of the transistors 406 and 408 are provided in Table 1. In each example, the threshold of the transistor 408 is lower than the threshold of the transistor 406. The difference in the threshold of the transistor 406 and the threshold of the transistor 408 defines the offset voltage that sets the trip voltage of the comparator 402. With the transistors 406 and 408 in sub-threshold: the current in the transistors 406 and 408 are approximately equal at the trip point of the comparator 402; the n factor are approximately the same for the transistors 406 and 408, and the difference in the thresholds is expressed as:

$${VT}_{g a p} = {Vth}_{N C H} - {Vth}_{N C {H}_{N A T}} + nVt * ln ( \frac{β {eff}_{N C {H}_{N A T}}}{β {eff}_{N C H}} ) \qquad ( 2 )$$

where:
Vth_{NCH} is the threshold voltage of the transistor 406;
Vth_{NCH}_{_{NAT}} Is the threshold voltage of the transistor 408;
n is the sub-threshold slope factor of the transistor 406 and the transistor 408, given as:

$$n = \frac{{C}_{o x} + {C}_{d e p}}{{C}_{o x}} = 1 + \frac{{C}_{d e p}}{{C}_{o x}}$$

where C_{dep} is the depletion layer capacitance and Cₒₓ is the oxide capacitance per unit area;
Vt is thermal voltage defined by

$$\frac{kT}{q} ,$$

where k is Boltzmann's constant, T is temperature, and q is the electronic charge;
βeff_{NCH} and βeff_{NCH}_{_{NAT}} are the effective betas of the transistor 406 and the transistor 408 using actual width and length of the transistors in operation, and equals (as a first approximation)

$${μ}_{eff} {C}_{o x} ( \frac{{W}_{eff}}{{L}_{eff}} ) ,$$

where:
μ_{eff} is the effective mobility;
W_{eff} is effective width; and
L_{eff} is effective length;
Vth_{NCH}−Vth_{NCH}_{_{NAT}} is the threshold voltage gap term of equation (2); and
nVt*ln

$$nVt * ln ( \frac{β {eff}_{N C {H}_{N A T}}}{β {eff}_{N C H}} )$$

is the temperature coefficient correction term of equation (2).

The trip voltage of the comparator 402 is the voltage across the inputs 302A and 302B of the comparator 402 at which the output 302C of the comparator 402 changes state. The trip voltage of the comparator 402 is expressed as:

$${V}_{trip} = \frac{V {T}_{gap} ( {R}_{T} + {R}_{M} )}{{R}_{M}} \qquad ( 3 )$$

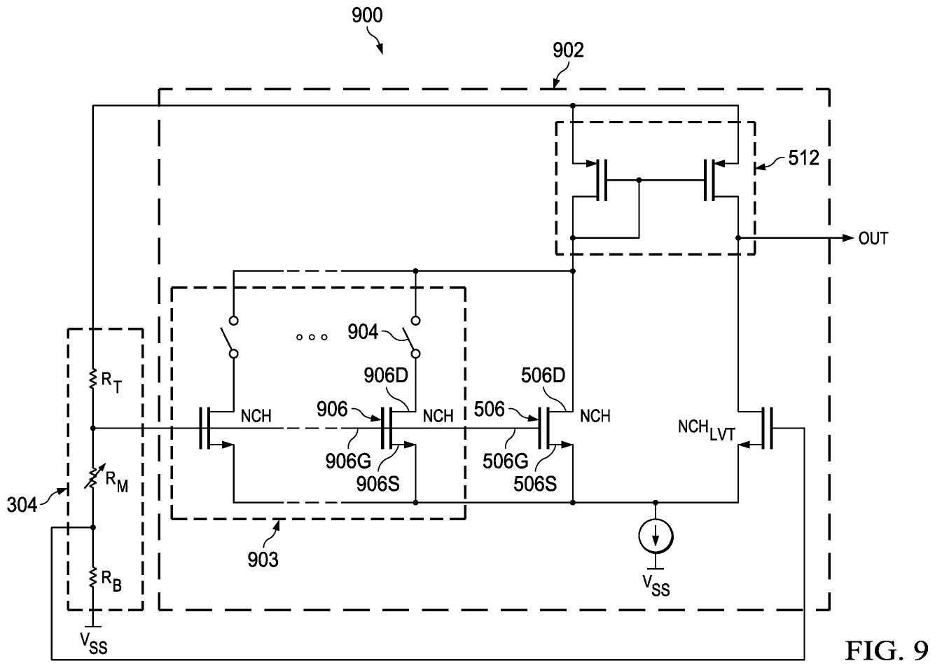

In implementations of the supply voltage supervisor circuit 400, temperature cancellation may be provided by adjusting the βeff ratio, and room temperature accuracy may be controlled by adjusting the resistance of the resistor 322 or the resistor 324. Examples of adjusting the βeff ratio are provided in FIGS. 9-12 and associated description.

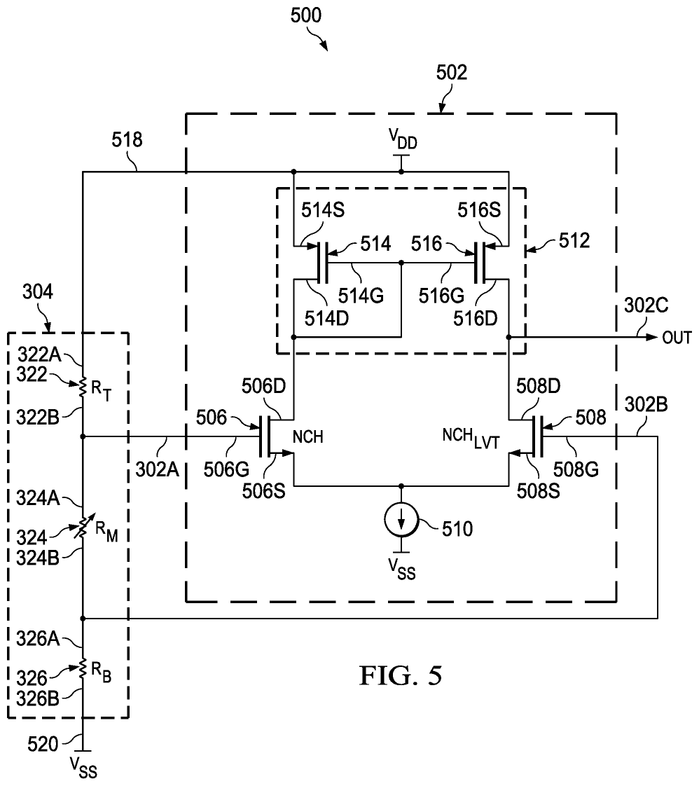

FIG. 5 shows a schematic diagram for an example supply voltage supervisor circuit 500 that generates a reference voltage based on different threshold voltages of the comparator input transistors in accordance with an example embodiment. The supply voltage supervisor circuit 500 includes a comparator 502, and a voltage divider 304. The voltage divider 304 divides the voltage provided on the power supply rail 518 to generate the voltages to be provided to the comparator 502. The voltage divider 304 includes a resistor 322, a variable resistor 324, and a resistor 326. A terminal 322A of the resistor 322 is coupled to the power supply rail 518. A terminal 324A of the resistor 324 is coupled to a terminal 322B of the resistor 322. A terminal 324B of the resistor 324 is coupled to a terminal 326A of the resistor 326. A terminal 326B of the resistor 326 is coupled to the ground rail 520.

The comparator 502 includes an input terminal 302A, an input terminal 302B, a transistor 506, a transistor 508, a current source 510, and a current mirror circuit 512. The input terminal 302A is coupled to the terminal 322B of the resistor 322 for receipt of a first divided power rail voltage. The input terminal 302B is coupled to the terminal 324B of the resistor 324 for receipt of a second divided power rail voltage. The current mirror circuit 512 includes a diode-connected transistor 514 and a transistor 516. The diode-connected transistor 514 includes a source terminal 514S coupled to the power supply rail 518, and gate terminal 514G coupled to a drain terminal 514D. The transistor 516 includes a source terminal 516S coupled to the power supply rail 518, a gate terminal 516G coupled to the gate terminal 514G of the diode-connected transistor 514, and a drain terminal 516D coupled to an output terminal 302C of the comparator 502.

The transistor 506 includes a gate terminal 506G coupled to the input terminal 302A, a drain terminal 506D coupled to the drain terminal 514D of the diode-connected transistor 514, and a source terminal 506S coupled to the current source 510. The transistor 508 includes a gate terminal 508G coupled to the input terminal 302B, a drain terminal 508D coupled to the drain terminal 516D of the transistor 516, and a source terminal 508S coupled to the current source 510.

The transistor 506 has a standard threshold voltage, and is a standard threshold voltage N-channel MOSFET in some implementations of the supply voltage supervisor circuit 500. The transistor 508 is low threshold voltage N-channel MOSFET. The threshold of the transistor 508 is lower than the threshold of the transistor 506. The difference in the threshold of the transistor 506 and the threshold of the transistor 508 defines the offset voltage that sets the trip voltage of the comparator 502. Examples of the transistors 506 and 508 suitable for use in the comparator 502 are provided in Table 1.

The trip voltage of the comparator 502 is expressed as:

$${V}_{trip} = \frac{V {T}_{gap} ( {R}_{T} + {R}_{M} + {R}_{B} )}{{R}_{M}} \qquad ( 4 )$$

Various implementations of the comparators 402 and 502 may apply different types of transistors 406/506 and 408/508 as shown in Table 1:

TABLE 1

| Implementation | Transistor 406/506 | Transistor 408/508 |
|---|---|---|
| 1 | Standard threshold voltage | Natural threshold voltage |
| | NMOS | NMOS |
| 2 | Low threshold voltage NMOS | Natural threshold voltage |
| | | NMOS |
| 3 | Standard threshold voltage | Depletion mode NMOS |
| | NMOS | |
| 4 | Low threshold voltage NMOS | Depletion mode NMOS |
| 5 | Standard threshold voltage | Low threshold voltage |
| | NMOS | NMOS |

Standard threshold voltage NMOS transistors have a threshold voltage of about +0.7 volts. Low threshold voltage NMOS transistors have a threshold voltage of about +0.45 volts. Natural threshold voltage NMOS transistors have a threshold voltage of about −60 millivolts. Depletion mode NMOS transistors have a threshold voltage of about −600 millivolts.

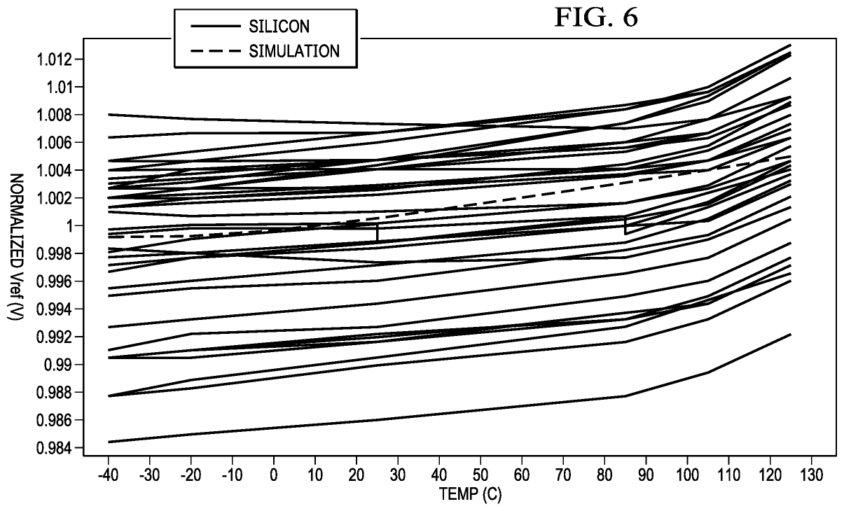

FIG. 6 shows a range of reference voltage values generated by thirty-six silicon implementations of the supply voltage supervisor circuit 500 and a reference voltage value produced by a simulation of the supply voltage supervisor circuit 500 relative to temperature. The illustrated reference voltage values are normalized with respect to a target value of reference voltage. FIG. 6 shows that the generated reference voltages values are within about 1.5% of the target reference voltage value over temperature, which makes them sufficiently accurate for use in a supply voltage supervisor circuit. The silicon implementations applied to produce the measurements shown in FIG. 6 have not been trimmed to compensate for temperature. Deviation from the target reference voltage value may be further reduced by adjusting the βeff ratio of one or more of the transistors of the supply voltage supervisor circuit 500, and by adjusting the resistance of the resistor 322 or the resistor 324 as explained herein.

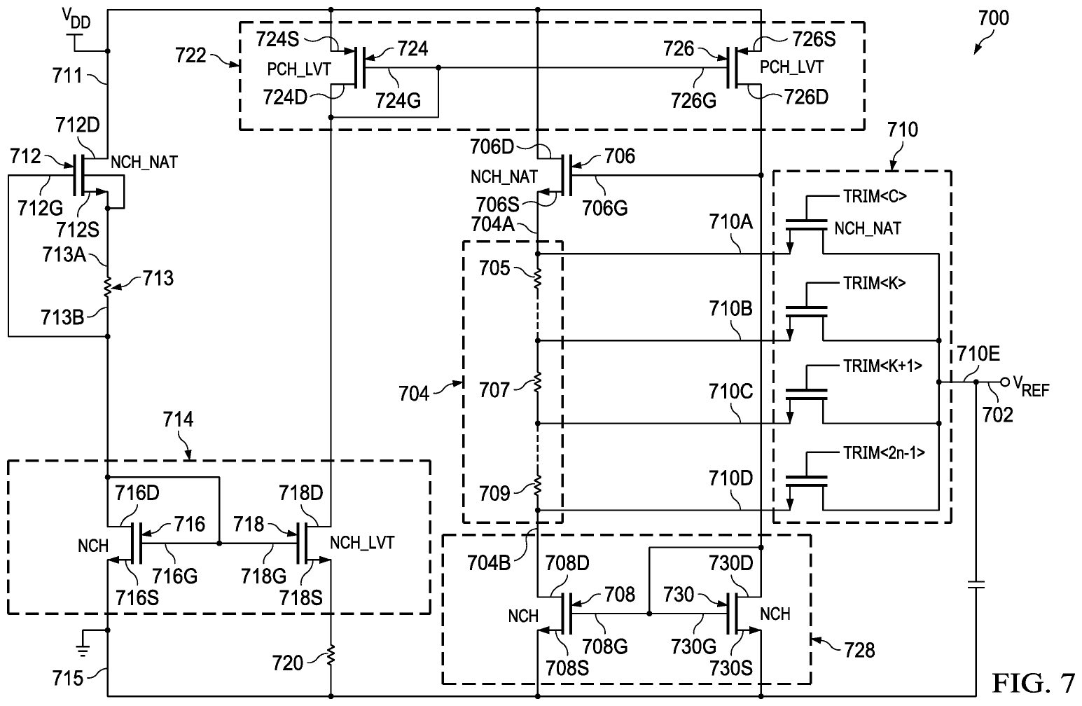

FIG. 7 shows an example reference voltage generation circuit 700 that generates a reference voltage based on different threshold voltages of transistors in accordance with another example embodiment. The reference voltage generation circuit 700 may be applied to generate a reference voltage (at V_{REF} 702) for use in a supply voltage supervisor circuit. For example, in an implementation of the supply voltage supervisor circuit 200, the reference voltage generation circuit 700 may replace the bandgap reference circuit 206. The reference voltage generation circuit 700 includes resistors 704, a transistor 706, a selector circuit 710, a transistor 712, a biasing circuit 714, a current mirror circuit 722, and a current mirror circuit 728. The resistors 704 are illustrated as including resistors 705, 707, and 709 coupled in series, but may include any number of resistors coupled in series. The selector circuit 710 is coupled to the resistors 704, and includes a plurality of input terminals 710A, 710B, 710C, and 710D, and an output terminal 710E. The output terminal 710E is coupled to an output terminal 702 of the reference voltage generation circuit 700 for providing a reference voltage produced at one of the resistors 705, 707, 709 of the resistors 604 to a comparator (e.g., the comparator 202). Each of the input terminals of the selector circuit 610 is coupled to a terminal of one of the resistors 705, 707, 709 of the resistors 704. The selector circuit 710 switchably couples one of the input terminals (as selected by a trim code TRIM< >) to the output terminal 710E. The reference voltage generation circuit 700 provides accuracy trim at room temperature by selectively connecting the inputs of the selector circuit 710 to the output of the selector circuit 710.

Current flows through the transistor 706 to the resistors 704. The transistor 706 is a natural N-channel MOSFET. The transistor 706 includes a drain terminal 706D coupled to the power supply rail 711, and a source terminal 706S coupled to a current input terminal 704A of the resistors 704. The transistor 708 of the current mirror circuit 728 sinks current from the resistors 704. The transistor 708 is a standard threshold voltage N-channel MOSFET. The transistor 708 includes a drain terminal 708D coupled to a current output terminal 704B of the resistors 704, and a source terminal 708S coupled to the ground rail 715. The difference in the threshold voltages of the transistor 706 and transistor 730 sets the reference voltage generated by the reference voltage generation circuit 700.

The transistor 712 induces current flow in the reference voltage generation circuit 700. The transistor 712 is a natural N-channel MOSFET. The transistor 712 includes a drain terminal 712D coupled to the power supply rail 711, a source terminal 712S coupled to a terminal 713A of a resistor 713, and a gate terminal 712G coupled to a terminal 713B of the resistor 713.

The biasing circuit 714 is coupled to the transistor 712, and includes a diode-connected transistor 716 and a transistor 718. The diode-connected transistor 716 is a standard threshold voltage N-channel MOSFET and the transistor 718 is low threshold voltage N-channel MOSFET. That is, the threshold of the transistor 718 is higher than the threshold of the transistor 712, and lower than the threshold of the transistor 708 and the transistor 716. The transistor 716 includes a drain terminal 716D and a gate terminal 716G coupled to the terminal 713B of the resistor 713. A source terminal 716S of the diode-connected transistor 716 is coupled to the ground rail 715. The transistor 718 includes a gate terminal 718G coupled to the gate terminal 716G of the diode-connected transistor 716, and a source terminal 718S coupled to the ground rail 715 via a resistor 720.

The current mirror circuit 722 sources the current flowing in the transistor 718. The current mirror circuit 722 includes a diode-connected transistor 724 and a transistor 726. The diode-connected transistor 724 and the transistor 726 are low threshold voltage P-channel MOSFETs. The diode-connected transistor 724 includes a source terminal 724S coupled to the power supply rail 711, and a drain terminal 724D and a gate terminal 724G coupled to the drain terminal 718D of the transistor 718. A source terminal 726S of the transistor 726 is coupled to the power supply rail 711. The transistor 726 includes a gate terminal 726G coupled to the gate terminal 724G of the diode-connected transistor 724, and a drain terminal 726D coupled to the gate terminal 706G of the transistor 706.

The current mirror circuit 728 sinks current flowing from the resistors 704 and the current mirror circuit 722. The current mirror circuit 728 includes a diode-connected transistor 730 and the transistor 708. Like the transistor 708, the diode-connected transistor 730 is a standard threshold voltage N-channel MOSFET. The diode-connected transistor 730 includes a source terminal 730S coupled to the ground rail 715, and a drain terminal 730D and gate terminal 730G coupled to the gate terminal 708G of the transistor 708 and the drain terminal 726D of the transistor 726.

The reference voltage generated by the reference voltage generation circuit 700 may be defined as:

$${V}_{R E F} = {Vth}_{N C H} - {Vth}_{N C {H}_{N A T}} + nVt * ln ( N * \frac{β {eff}_{N C {H}_{N A T}}}{β {eff}_{N C H}} ) - ( \frac{M}{N} ) * ( \frac{{R}_{TRIM}}{{R}_{B I A S}} ) * [ {Vth}_{N C H} - {Vth}_{N C {H}_{LVT}} + nVt * ln ( \frac{{I}_{S U P}}{{I}_{B I A S}} * \frac{β {eff}_{N C {H}_{LVT}}}{β {eff}_{N C H}} ) ] \qquad ( 5 )$$

where:
M is size of the transistor 726 relative to the diode-connected transistor 724. For example, the transistor 726 is M times larger than the diode-connected transistor 724.
N is size of the diode-connected transistor 730 relative to the transistor 708. For example, the diode-connected transistor 730 is N times larger than the transistor 708.
R_{TRIM} is resistance of the resistors 704.
R_{BIAS} is resistance of the resistor 720.
I_{BIAS} is current flowing through the transistor 718.
I_{SUP} is current flowing through the diode-connected transistor 716.

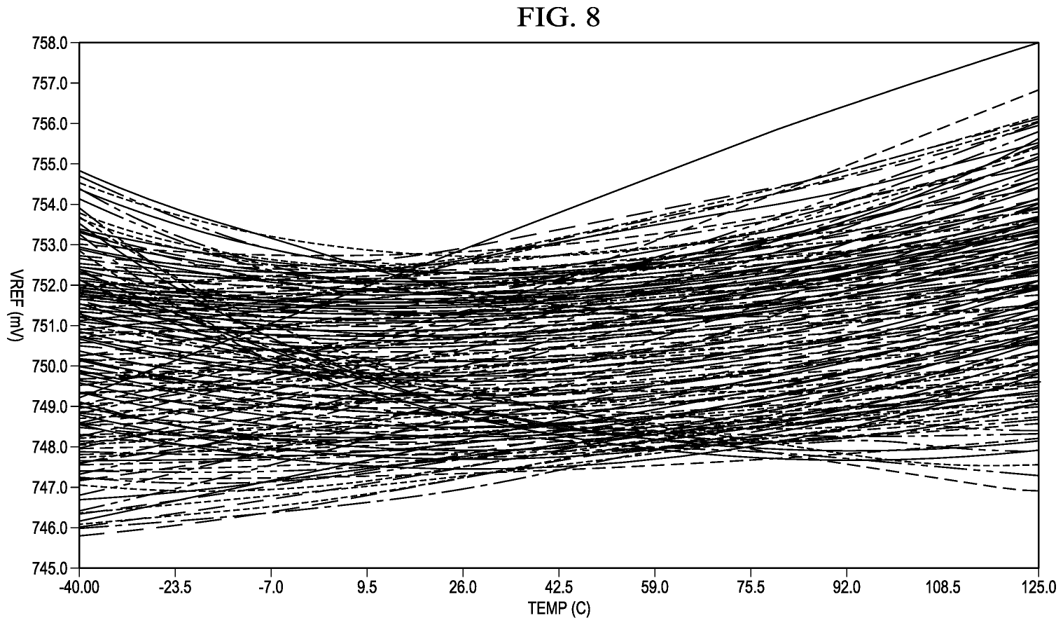

FIG. 8 shows reference voltage versus temperature for examples of the reference voltage generation circuit 700 of FIG. 7. The reference voltage value of each of the reference voltage generation circuits 700 has been trimmed using the selector circuit 710 to improve the accuracy of the reference voltage values at 25° Celsius (C.). As a result, the reference voltage values deviate from a nominal reference voltage value (e.g., 750 mv) by less than 1% at 25° C.

FIGS. 9-12 shows example supply voltage supervisor circuits that generate a reference voltage based on different threshold voltages of the comparator input transistors and include trim transistors in accordance with example embodiments. FIG. 9 shows an example of a supply voltage supervisor circuit 900 that includes temperature trim based on the effective beta of the standard threshold N-channel MOSFET. The supply voltage supervisor circuit 900 is similar to the supply voltage supervisor circuit 500. The supply voltage supervisor circuit 900 includes the voltage divider 304 and a comparator 902. The comparator 902 is similar to the comparator 502 and includes transistors 903 coupled in parallel with the transistor 506. One or more of the transistors 903 may be selected to increase the effective beta associated with the transistor 506. By connecting one or more of the transistors 903 in parallel with the transistor 506, the effective channel width of the parallel transistor is increased to increase effective beta. For example, the transistor 906 includes a source terminal 906S coupled to the source terminal 506S of the transistor 506, and a gate terminal 906G coupled to the gate terminal 506G of the transistor 506. The switch 904 may be closed to couple the drain terminal 906D of the transistor 906 to the drain terminal 506D of the transistor 506, thereby changing the effective beta of the paralleled transistors and changing the value of the temperature coefficient correction term of equation (2).

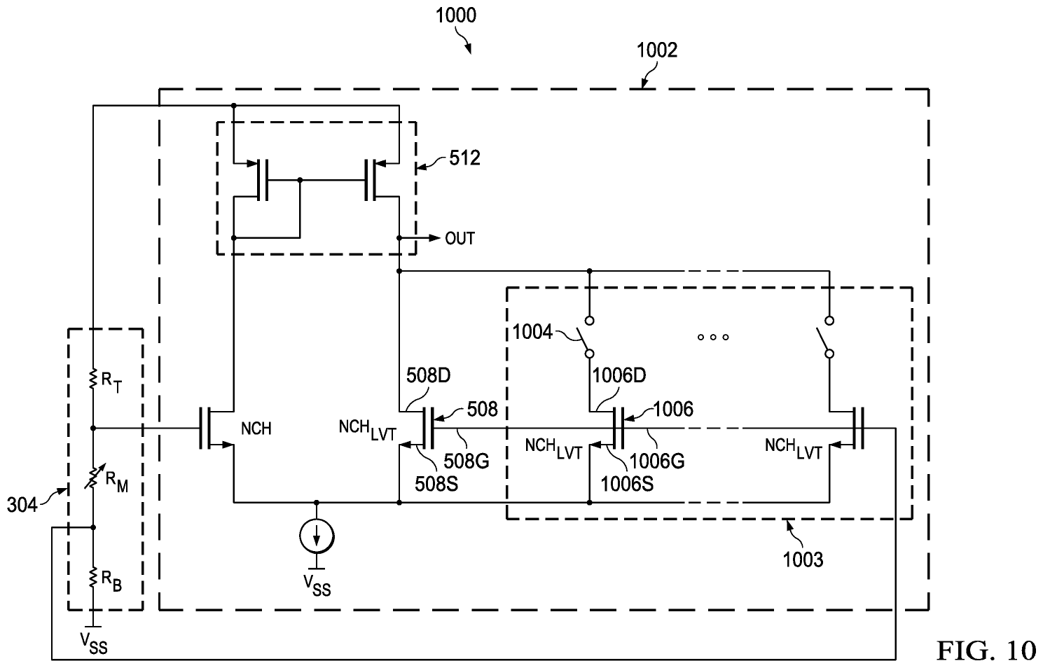

FIG. 10 shows an example of a supply voltage supervisor circuit 1000 that includes temperature trim based on the effective beta of the low threshold N-channel MOSFET. The supply voltage supervisor circuit 1000 is similar to the supply voltage supervisor circuit 500. The supply voltage supervisor circuit 1000 includes the voltage divider 304 and a comparator 1002. The comparator 1002 is similar to the comparator 502 and includes transistors 1003 coupled in parallel with the transistor 508. One or more of the transistors 1003 may be selected to increase the effective beta associated with the transistor 508. For example, the transistor 1006 includes a source terminal 1006S coupled to the source terminal 508S of the transistor 508, and a gate terminal 1006G coupled to the gate terminal 508G of the transistor 508. The switch 1004 may be closed to couple the drain terminal 1006D of the transistor 1006 to the drain terminal 508D of the transistor 508, thereby changing the value of the temperature coefficient correction term of equation (2).

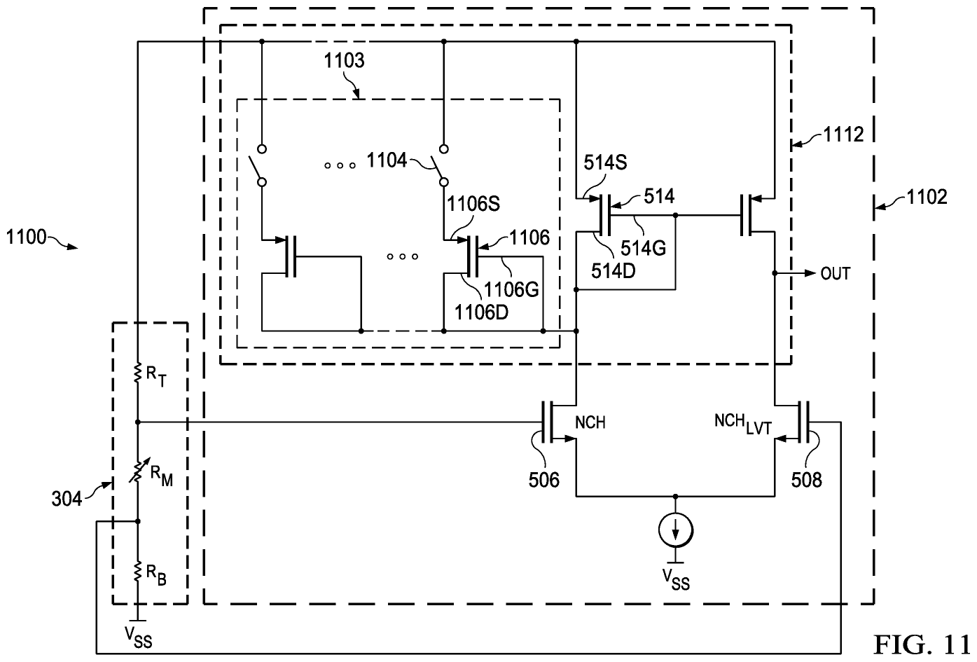

FIG. 11 shows an example of a supply voltage supervisor circuit 1100 that includes temperature trim based on the ratio of bias current provided to the input transistors. The supply voltage supervisor circuit 1100 is similar to the supply voltage supervisor circuit 500. The supply voltage supervisor circuit 1100 includes the voltage divider 304 and a comparator 1102. The comparator 1102 is similar to the comparator 502 and includes transistors 1103 coupled in parallel with the diode-connected transistor 514. One or more of the transistors 1103 may be selected to increase the current flowing to the diode-connected transistor 514. For example, the transistor 1106 includes a drain terminal 1106D coupled to the drain terminal 514D of the diode-connected transistor 514, and a gate terminal 1106G coupled to the gate terminal 514G of the diode-connected transistor 514. The switch 1104 may be closed to couple the source terminal 1106S of the transistor 1106 to the source terminal 514S of the diode-connected transistor 514, thereby changing the value of the temperature coefficient correction term as:

$${VT}_{g a p} = {Vth}_{N C H} - {Vth}_{N C {H}_{LVT}} + nVt * ln ( \frac{β {eff}_{N C {H}_{LVT}}}{β {eff}_{N C H}} * \frac{{I}_{N C H}}{{I}_{N C {H}_{LVT}}} ) \qquad ( 6 )$$

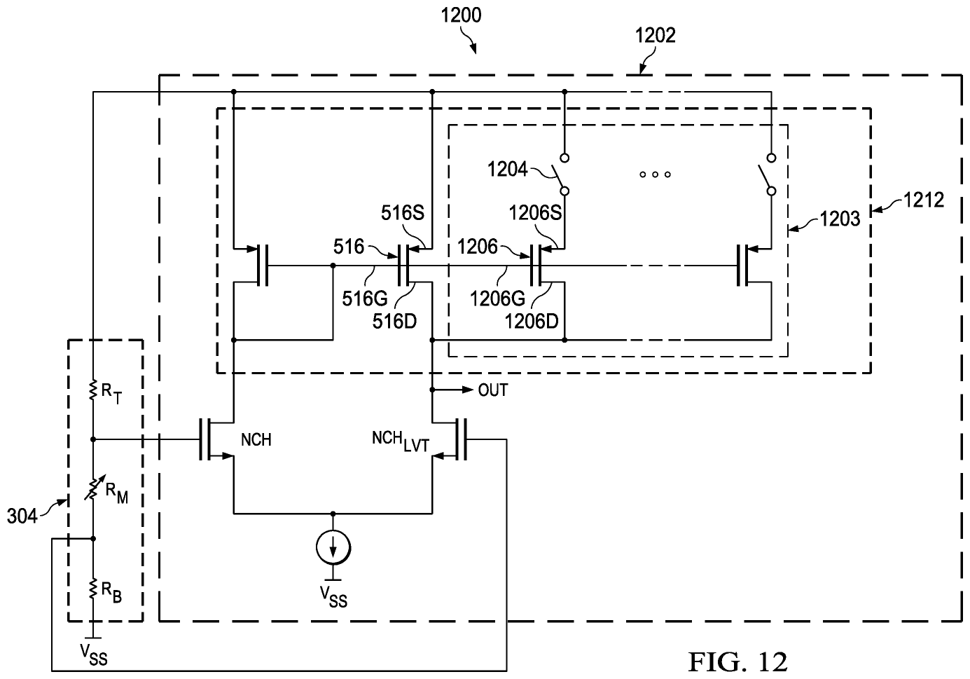

FIG. 12 shows an example of a supply voltage supervisor circuit 1200 that includes temperature trim based on the ratio of bias current provided to the input transistors. The supply voltage supervisor circuit 1200 is similar to the supply voltage supervisor circuit 500. The supply voltage supervisor circuit 1200 includes the voltage divider 304 and a comparator 1202. The comparator 1202 is similar to the comparator 502 and includes transistors 1203 coupled in parallel with the transistor 516. One or more of the transistors 1203 may be selected to increase the current flowing to the transistor 516. For example, the transistor 1206 includes a drain terminal 1206D coupled to the drain terminal 516D of the transistor 516, and a gate terminal 1206G coupled to the gate terminal 516G of the transistor 516. The switch 1204 may be closed to couple the source terminal 1206S of the transistor 1206 to the source terminal 516S of the transistor 516, thereby changing the value of the temperature coefficient correction term of equation (6).

While certain elements in the above description of the example embodiments may be illustrated as NMOS or PMOS devices, other devices may be used instead of the identified devices. For example, PMOS devices may be used instead of NMOS devices, and vice versa. Furthermore, bipolar transistors (NPN or PNP) or junction transistors may be used instead. In this description, the terms “couple” or “couples” may cover connections, communications, or signal paths that enable a functional relationship consistent with the description of the present disclosure. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A. Also, in this description, the recitation “based on” means “based at least in part on.” Therefore, if X is based on Y, then X may be a function of Y and any number of other factors.

Modifications are possible in the described embodiments, and other embodiments are possible, within the scope of the claims.

What is claimed is:

1. A supply voltage supervisor circuit, comprising:
a comparator circuit, comprising:
a first input terminal;
a second input terminal;
a first transistor having a first threshold voltage, and comprising a first terminal coupled to the first input terminal; a second transistor having a second threshold voltage different than the first threshold voltage, and comprising:
a first terminal coupled to the second input terminal; and
a second terminal coupled to a second terminal of the first transistor;
and wherein a trip point of the comparator circuit is based on a difference of the first threshold voltage and the second threshold voltage.

2. The supply voltage supervisor circuit of claim 1, wherein the comparator circuit comprises:
a current mirror circuit comprising:
a diode-connected transistor comprising:
a first terminal coupled to a power supply rail;
a second terminal coupled to a third terminal of the first transistor; and
a third terminal coupled to the third terminal of the first transistor; and
a third transistor comprising:
a first terminal coupled to the power supply rail;
a second terminal coupled to a third terminal of the second transistor; and
a third terminal coupled to the third terminal of the diode-connected transistor.

3. The supply voltage supervisor circuit of claim 2, wherein:
the diode-connected transistor is a first diode-connected transistor; and
the current mirror circuit comprises:
a second diode-connected transistor comprising:
a first terminal switchably coupled to the power supply rail;
a second terminal coupled to a second terminal of the first diode-connected transistor; and
a third terminal coupled to the third terminal of the first diode-connected transistor.

4. The supply voltage supervisor circuit of claim 2, wherein the current mirror circuit comprises:
a fourth transistor comprising:
a first terminal switchably coupled to the power supply rail;
a second terminal coupled to the second terminal of the third transistor; and
a third terminal coupled to the third terminal of the third transistor.

5. The supply voltage supervisor circuit of claim 1, further comprising:
a voltage divider comprising:
a first resistor comprising:
a first terminal coupled to a power supply rail; and
a second terminal coupled to the first input terminal; and
a second resistor comprising:
a first terminal coupled to the first input terminal; and
a second terminal coupled to a ground rail.

6. The supply voltage supervisor circuit of claim 1, further comprising:
a voltage divider comprising:
a first resistor comprising:
a first terminal coupled to a power supply rail;
a second terminal coupled to the first input terminal; and
a second resistor comprising:
a first terminal coupled to the first input terminal; and
a second terminal coupled to the second input terminal; and
a third resistor comprising;
a first terminal coupled to the second input terminal; and
a second terminal coupled to a ground rail.

7. The supply voltage supervisor circuit of claim 1, further comprising:
a third transistor comprising:
a first terminal coupled to the first terminal of the first transistor;
a second terminal coupled to the second terminal of the first transistor; and
a third terminal switchably coupled to the third terminal of the first transistor.

8. The supply voltage supervisor circuit of claim 1, further comprising:
a third transistor comprising:
a first terminal coupled to the first terminal of the second transistor;
a second terminal coupled to the second terminal of the second transistor; and
a third terminal switchably coupled to the third terminal of the second transistor.

9. The supply voltage supervisor circuit of claim 1 wherein:
the first transistor is a standard threshold voltage N-channel metal oxide semiconductor field effect transistor (MOSFET); and
the second transistor is a natural threshold voltage N-channel MOSFET, a low threshold voltage N-channel MOSFET, or a depletion mode N-channel MOSFET.

10. The supply voltage supervisor circuit of claim 1 wherein:
the first transistor is low threshold voltage N-channel MOSFET; and
the second transistor is a natural threshold voltage N-channel MOSFET or a depletion mode N-channel MOSFET.

11. A supply voltage supervisor circuit, comprising:
a comparator circuit; and
a reference voltage circuit comprising:
a reference output terminal coupled to an input terminal of the comparator circuit;
a plurality of resistors coupled in series;
an N-channel natural threshold voltage metal oxide semiconductor field effect transistor (MOSFET) comprising:
a first terminal coupled to a power rail; and
a second terminal coupled to a current input terminal of the resistors;
an N-channel standard threshold voltage MOSFET comprising:
a first terminal coupled to a current output terminal of the resistors;
a second terminal coupled to a ground rail; and
a third terminal coupled to a third terminal of the N-channel natural threshold voltage MOSFET; and
a selector circuit comprising:
a plurality of input terminals coupled to the resistors; and
a selector output terminal coupled to the reference output terminal.

12. The supply voltage supervisor circuit of claim 11, wherein:
the N-channel natural threshold voltage MOSFET is a first N-channel natural threshold voltage MOSFET; and
the supply voltage supervisor comprises:
a second N-channel natural threshold voltage MOSFET comprising a first terminal coupled to a power supply rail;
a resistor comprising:
a first terminal coupled to a second terminal of the second N-channel natural threshold voltage MOSFET; and
a second terminal coupled to a third terminal of the second N-channel natural threshold voltage MOSFET.

13. The supply voltage supervisor circuit of claim 12, wherein:
the N-channel standard threshold voltage MOSFET is a first N-channel standard threshold voltage MOSFET; and
the supply voltage supervisor circuit comprises:
a biasing circuit comprising:
a second N-channel standard threshold voltage MOSFET connected as a diode, and comprising:
a first terminal and a second terminal coupled to the second terminal of the resistor; and
a third terminal coupled to a ground rail; and
an N-channel low threshold voltage MOSFET comprising:
a first terminal coupled to the ground rail; and
a second terminal coupled to the second terminal of the second N-channel standard threshold voltage MOSFET.

14. The supply voltage supervisor circuit of claim 13, wherein:
the supply voltage supervisor circuit comprises:
a current mirror circuit comprising:
a first P-channel low threshold voltage MOSFET connected as a diode, and comprising:
a first terminal coupled to the power rail;
a second terminal and a third terminal coupled to a third terminal of the N-channel low threshold voltage MOSFET; and
a second P-channel low threshold voltage MOSFET comprising:
a first terminal coupled to the power rail;
a second terminal coupled to the second terminal of the first P-channel low threshold voltage MOSFET; and
a third terminal coupled to a third terminal of the first N-channel natural threshold voltage MOSFET.

15. The supply voltage supervisor circuit of claim 14, wherein:
the current mirror circuit is a first current mirror circuit; and
the supply voltage supervisor circuit further comprises:
a second current mirror circuit comprising:
a third N-channel standard threshold voltage MOSFET connected as a diode, and comprising:
a first terminal and a second terminal coupled to the third terminal of the second P-channel low threshold voltage MOSFET; and
a third terminal coupled to a ground rail; and
the first N-channel standard threshold voltage MOSFET.

16. A comparator circuit, comprising:
a first input terminal;
a second input terminal;
a first transistor having a first threshold voltage, and comprising a first terminal coupled to the first input terminal;
a second transistor having a second threshold voltage that is lower than the first threshold voltage, and comprising:
a first terminal coupled to the second input terminal; and
a second terminal coupled to a second terminal of the first transistor;
a current mirror circuit comprising:
a diode-connected transistor comprising:
a first terminal coupled to a power supply rail;
a second terminal and a third terminal coupled to a third terminal of the first transistor; and
a third transistor comprising:
a first terminal coupled to the power supply rail;
a second terminal coupled to a third terminal of the second transistor; and
a third terminal coupled to the third terminal of the diode-connected transistor'
wherein a trip point of the comparator circuit is based on a difference of the first threshold voltage and the second threshold voltage.

17. The comparator circuit of claim 16, wherein:
the diode-connected transistor is a first diode-connected transistor; and
the current mirror circuit comprises:
a second diode-connected transistor comprising:
a first terminal switchably coupled to the power supply rail;
a second terminal coupled to a second terminal of the first diode-connected transistor; and
a third terminal coupled to the third terminal of the first diode-connected transistor.

18. The comparator circuit of claim 16, wherein the current mirror circuit comprises:
a fourth transistor comprising:
a first terminal switchably coupled to the power supply rail;
a second terminal coupled to the second terminal of the third transistor; and
a third terminal coupled to the third terminal of the third transistor.

19. The comparator circuit of claim 16, further comprising:
a fourth transistor comprising:
a first terminal coupled to the first terminal of the first transistor;
a second terminal coupled to the second terminal of the first transistor; and
a third terminal switchably coupled to the third terminal of the first transistor.

20. The comparator circuit of claim 16, further comprising:
a fourth transistor comprising:
a first terminal coupled to the first terminal of the second transistor;
a second terminal coupled to the second terminal of the second transistor; and
a third terminal switchably coupled to the third terminal of the second transistor.

21. The comparator circuit of claim 16, wherein:
the first transistor is standard threshold voltage N-channel metal oxide semiconductor field effect transistor (MOSFET); and
the second transistor is a natural threshold voltage N-channel MOSFET, a low threshold voltage N-channel MOSFET, or a depletion mode N-channel MOSFET.

22. The comparator circuit of claim 16, wherein:
the first transistor is low threshold voltage N-channel MOSFET; and
the second transistor is a natural threshold voltage N-channel MOSFET or a depletion mode N-channel MOSFET.
